(19) United States
(12) Patent Application Publication
(10) Pub. No.: US 2018/0083142 A1
(43) Pub. Date: Mar. 22, 2018

(54) MANUFACTURE METHOD OF TFT SUBSTRATE AND MANUFACTURED TFT SUBSTRATE

(71) Applicant: Shenzhen China Star Optoelectronics Technology Co., Ltd., Shenzhen City (CN)

(72) Inventor: Shipeng Chi, Shenzhen City (CN)

(21) Appl. No.: 15/106,812

(22) PCT Filed: Apr. 26, 2016
(86) PCT No.: PCT/CN2016/080190

§ 371 Date: Jun. 20, 2016

(30) Foreign Application Priority Data
Mar. 23, 2016 (CN) 201610169584.4

(51) Int. Cl. H01L 29/786; H01L 27/12; H01L 29/45; H01L 29/49; H01L 29/66

(52) U.S. Cl. CPC H01L 29/78645; H01L 27/1222; H01L 27/1274; H01L 27/1288; H01L 29/458; H01L 27/3262; H01L 29/78621; H01L 29/78696; H01L 29/78675; H01L 29/66757; H01L 29/4908

(57) ABSTRACT

The present invention provides a manufacture method of a TFT substrate and a manufactured TFT substrate. In the manufacture method of the TFT substrate according to the present invention, by locating the first lightly doped offset region and the second lightly doped offset region in the TFT, the off state current of the TFT can be reduced; meanwhile, by utilizing the first gate and the second gate to compose the dual gate structure, the influence of the first lightly doped offset region and the second lightly doped offset region to the TFT on state current can be reduced, and the first gate and the second gate are connected, and controlled by the same gate voltage, and no additional voltage is required; the structure is simple and the electrical property is excellent, and the manufactured TFT substrate possesses the better electrical property.

### FIELD OF THE INVENTION

The present invention relates to a display technology field, and more particularly to a manufacture method of a TFT substrate and a manufactured TFT substrate.

### BACKGROUND OF THE INVENTION

The OLED is a flat panel display technology which has great prospects for development. It possesses extremely excellent display performance, and particularly the properties of self-illumination, simple structure, ultra thin, fast response speed, wide view angle, low power consumption and capability of realizing flexible display, and therefore is considered as the “dream display”. Meanwhile, the investment for the production equipments is far smaller than the TFT-LCD. It has been favored by respective big display makers and has become the main selection of the third generation display element of the display technology field. At present, the OLED has reached the point before mass production. With the further research and development, the new technologies constantly appear, and someday, there will be a breakthrough for the development of the OLED display elements.

The OLED can be categorized into two major types according to the driving ways, which are the Passive Matrix OLED (PMOLED) and the Active Matrix OLED (AMOLED), i.e. two types of the direct addressing and the Thin Film Transistor matrix addressing. The AMOLED comprises pixels arranged in array and belongs to active display type, which has high lighting efficiency and is generally utilized for the large scale display devices of high resolution.

At present, the AMOLED gradually becomes mature. In the AMOLED, it requires the current for driving. The Low Temperature Poly-Silicon (LTPS) has larger mobility, and the Thin Film Transistor (TFT) manufactured with the active layer can satisfy the current drive mode of the AMOLED. The Low Temperature Poly-Silicon Thin Film Transistor (LTPS TFT) has higher mobility and can achieve the higher on state current. However, the defect due to the grain existence in the LTPS will lead to the appearance of the higher off state current as the LTPS TFT is in off state. For decreasing the off state current of the LTPS TFT, the Lightly Doped Offset structure can be utilized. There are more researches about the Lightly Doped Offset structure at present. Nevertheless, the Lightly Doped Offset structure forms the high resistance region which will reduce the on state current of the LTPS TFT. For gaining the higher on state current, the improvement can be performed to the Lightly Doped Offset structure.

In the LTPS TFT having the Lightly Doped Offset structure, there is no carrier accumulation in the Lightly Doped Offset region, and the resistance is higher. As the TFT is in the off state, the off state current can be effectively reduced but as the TFT is in the on state, the existence of the Lightly Doped Offset region similarly reduces the on state current, and affects the switch property of the LTPS TFT.

### SUMMARY OF THE INVENTION

An objective of the present invention is to provide a manufacture method of a TFT substrate. By locating the first lightly doped offset region and the second lightly doped offset region in the TFT to reduce the off state current of the TFT, and meanwhile, utilizing the first gate and the second gate to compose the dual gate structure to reduce the influence of the first lightly doped offset region and the second lightly doped offset region to the TFT on state current, and the structure is simple and the electrical property is excellent, and the manufactured TFT substrate possesses the better electrical property.

Another objective of the present invention is to provides a manufacture TFT substrate which utilizes the lightly doped offset structure to reduce the off state current of the TFT, and utilizes the dual gate structure to reduce the influence of the lightly doped offset structure to the TFT on state current, and the structure is simple and the electrical property is excellent.

For realizing the aforesaid objectives, the present invention provides a manufacture method of a TFT substrate, comprising steps of:

step 1, providing a substrate, and forming an active layer on the substrate, and implementing ion implantation to the active layer and defining a channel region on the active layer;

step 2, depositing an isolation layer and a first metal layer on the active layer and the substrate, and employing one mask for patterning the first metal layer and the isolation layer to obtain a first gate and a gate isolation layer, of which widths are equal to a width of the channel region of the active layer, and two ends in a width direction are aligned;

employing the first gate and the gate isolation layer to be a stopper layer, and implementing ion implantation to the active layer to obtain a first ion heavily doped region and a second ion heavily doped region, which are respectively at two sides of the channel region;

step 3, depositing a second metal layer on the first gate, the active layer and the substrate, and employing one mask for patterning the second metal layer to obtain a source and a drain, which are at two sides of the active layer and respectively contact with the first ion heavily doped region and the second ion heavily doped region of the active layer;

a portion of the first ion heavily doped region contacting with the source is defined to be a source contact region; a portion of the second ion heavily doped region contacting with the drain is defined to be a drain contact region;

the source, the drain and the first gate are employed to be a stopper layer to etch a portion of the first ion heavily doped region between the source and the first gate, and a portion of the second ion heavily doped region between the first gate and the drain for removing an upper portion, of which an ion concentration is higher, and preserving a lower portion, of which an ion concentration is lower, and thus to obtain a first lightly doped offset region between the source contact region and the channel region, and a second lightly doped offset region between the channel region and the drain contact region;

step 4, depositing a passivation protective layer on the source, the drain, the active layer and the first gate, and employing one mask for patterning the passivation protective layer to respectively form a first via, a second via and a third via correspondingly above the source, the drain and the first gate;

step 5, depositing a conductive layer on the passivation protective layer, and employing one mask for patterning the conductive layer to obtain a first contact electrode, a second contact electrode and a second gate, and the first contact electrode and the second contact electrode are respectively coupled with the source and the drain through the first via and the second via, and the second gate is coupled to the first gate through the third via;

a width of the second gate is larger than a width of the first gate, and two sides of the second gate respectively cover the first lightly doped offset region and the second lightly doped offset region at the two sides of the first gate.

In the step 1, a specific implementation of forming the active layer on the substrate is: depositing an amorphous silicon thin film on the substrate, and after employing solid phase crystallization to convert the amorphous silicon film into a low temperature polysilicon film, employing one mask for patterning the low temperature polysilicon film to obtain the active layer.

The channel region is a N type ion lightly doped region, and the source contact region and the drain contact region are P type ion heavily doped regions, and the first lightly doped offset region and the second lightly doped offset region are P type ion lightly doped regions; or the channel region is a P type ion lightly doped region, and the source contact region and the drain contact region are N type ion heavily doped regions, and the first lightly doped offset region and the second lightly doped offset region are N type ion lightly doped regions.

A first overlap region is formed between a left side of the second gate and a right side of the source, and a second overlap region is formed between a right side of the second gate and a left side of the drain.

All materials of the first contact electrode, the second contact electrode and the second gate are transparent conductive metal oxide substance.

The present invention further provides a TFT substrate, comprising a substrate, an active layer located on the substrate, a source and a drain located on the active layer and the substrate, a gate isolation layer located on the active layer, a first gate located on the gate isolation layer, a passivation protective layer located on the source, the drain, the active layer and the first gate, and a first contact electrode, a second contact electrode and a second gate located on the passivation protective layer;

the active layer comprises a channel region in the middle, and a source contact region and a drain contact region at two ends, a first lightly doped offset region between the source contact region and the channel region, and a second lightly doped offset region between the channel region and the drain contact region;

a first gate and a gate isolation layer, of which widths are equal to a width of the channel region of the active layer, and two ends in a width direction are aligned;

the passivation protective layer comprises a first via, a second via and a third via, which are correspondingly above the source, the drain and the first gate, respectively; the first contact electrode and the second contact electrode are respectively coupled with the source and the drain through the first via and the second via, and the second gate is coupled to the first gate through the third via;

a width of the second gate is larger than a width of the first gate, and two sides of the second gate respectively cover the first lightly doped offset region and the second lightly doped offset region at the two sides of the first gate.

Upper surfaces of the first lightly doped offset region and the second lightly doped offset region are lower than upper surfaces of the channel region, the source contact region and the drain contact region.

The channel region is a N type ion lightly doped region, and the source contact region and the drain contact region are P type ion heavily doped regions, and the first lightly doped offset region and the second lightly doped offset region are P type ion lightly doped regions; or the channel region is a P type ion lightly doped region, and the source contact region and the drain contact region are N type ion heavily doped regions, and the first lightly doped offset region and the second lightly doped offset region are N type ion lightly doped regions.

A first overlap region is formed between a left side of the second gate and a right side of the source, and a second overlap region is formed between a right side of the second gate and a left side of the drain.

All materials of the first contact electrode, the second contact electrode and the second gate are transparent conductive metal oxide substance.

The present invention further provides a TFT substrate, comprising a substrate, an active layer located on the substrate, a source and a drain located on the active layer and the substrate, a gate isolation layer located on the active layer, a first gate located on the gate isolation layer, a passivation protective layer located on the source, the drain, the active layer and the first gate, and a first contact electrode, a second contact electrode and a second gate located on the passivation protective layer;

the active layer comprises a channel region in the middle, and a source contact region and a drain contact region at two ends, a first lightly doped offset region between the source contact region and the channel region, and a second lightly doped offset region between the channel region and the drain contact region;

a first gate and a gate isolation layer, of which widths are equal to a width of the channel region of the active layer, and two ends in a width direction are aligned;

the passivation protective layer comprises a first via, a second via and a third via, which are correspondingly above the source, the drain and the first gate, respectively; the first contact electrode and the second contact electrode are respectively coupled with the source and the drain through the first via and the second via, and the second gate is coupled to the first gate through the third via;

a width of the second gate is larger than a width of the first gate, and two sides of the second gate respectively cover the first lightly doped offset region and the second lightly doped offset region at the two sides of the first gate;

wherein upper surfaces of the first lightly doped offset region and the second lightly doped offset region are lower than upper surfaces of the channel region, the source contact region and the drain contact region;

wherein the channel region is a N type ion lightly doped region, and the source contact region and the drain contact region are P type ion heavily doped regions, and the first lightly doped offset region and the second lightly doped offset region are P type ion lightly doped regions; or the channel region is a P type ion lightly doped region, and the source contact region and the drain contact region are N type ion heavily doped regions, and the first lightly doped offset region and the second lightly doped offset region are N type ion lightly doped regions.

The benefits of the present invention are: the present invention provides the manufacture method of the TFT substrate, and by locating the first lightly doped offset region and the second lightly doped offset region in the TFT, the off state current of the TFT can be reduced; meanwhile, by utilizing the first gate and the second gate to compose the dual gate structure, the influence of the first lightly doped offset region and the second lightly doped offset region to the TFT on state current can be reduced, and the first gate and the second gate are connected, and controlled by the same gate voltage, and no additional voltage is required; the structure is simple and the electrical property is excellent, and the manufactured TFT substrate possesses the better electrical property. The manufactured TFT substrate of the present invention utilizes the lightly doped offset structure to reduce the off state current of the TFT, and utilizes the dual gate structure to reduce the influence of the lightly doped offset structure to the TFT on state current, and the structure is simple and the electrical property is excellent.

In order to better understand the characteristics and technical aspect of the invention, please refer to the following detailed description of the present invention is concerned with the diagrams, however, provide reference to the accompanying drawings and description only and is not intended to be limiting of the invention.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a flowchart of a manufacture method of a TFT substrate according to the present invention;

FIG. 2 is a diagram of the step 1 of a manufacture method of a TFT substrate according to the present invention;

FIGS. 3-5 are diagrams of the step 2 of a manufacture method of a TFT substrate according to the present invention;

FIGS. 6-7 are diagrams of the step 3 of a manufacture method of a TFT substrate according to the present invention;

FIG. 8 is a diagram of the step 4 of a manufacture method of a TFT substrate according to the present invention;

FIGS. 9-10 are diagrams of the step 5 of a manufacture method of a TFT substrate according to the present invention.

### DETAILED DESCRIPTION OF PREFERRED EMBODIMENTS

For better explaining the technical solution and the effect of the present invention, the present invention will be further described in detail with the accompanying drawings and the specific embodiments.

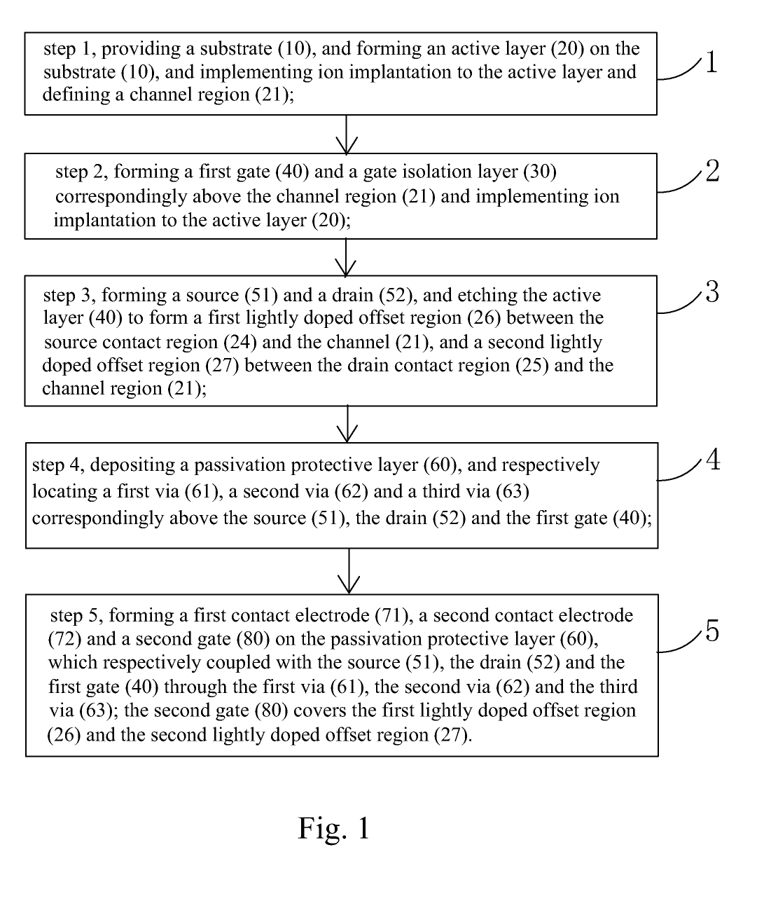

Please refer to FIG. 1. The present invention provides a manufacture method of a TFT substrate, comprising steps of:

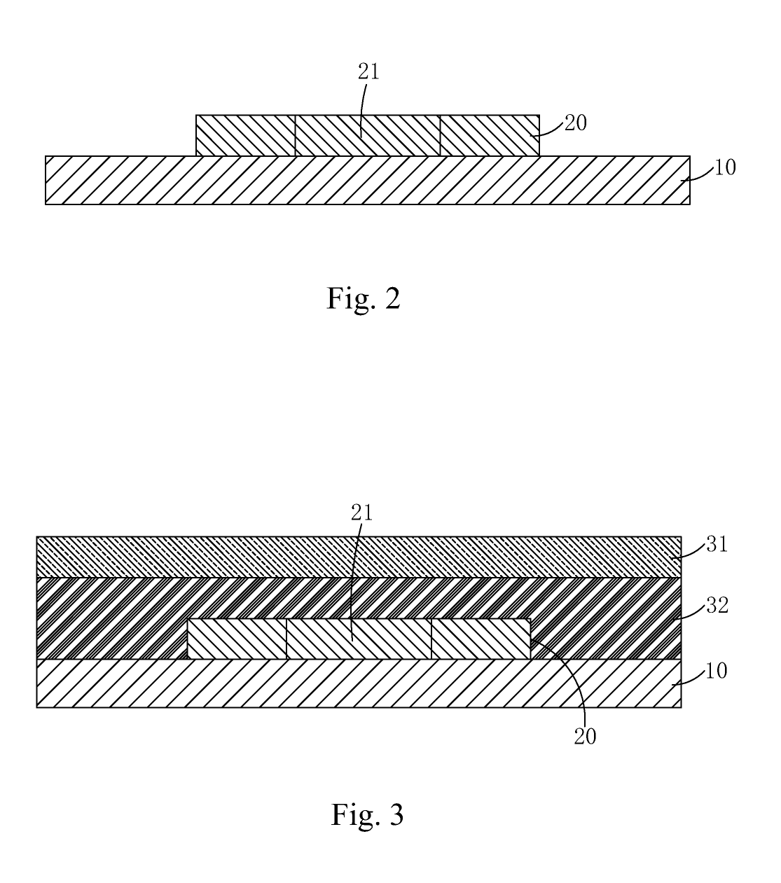

step 1, as shown in FIG. 2, providing a substrate 10, and forming an active layer 20 on the substrate 10, and implementing ion implantation to the active layer 20 and defining a channel region 21 on the active layer 20.

Specifically, the substrate 10 is a glass substrate.

In the step 1, a specific implementation of forming the active layer 20 on the substrate 10 is: depositing an amorphous silicon (a-Si) thin film on the substrate 10, and after employing SPC (Solid-Phase-Crystallization) to convert the amorphous silicon film into a low temperature polysilicon film, employing one mask for patterning the low temperature polysilicon film to obtain the active layer 20.

Specifically, in the step 1, by implementing N type (or P type) ion implantation to the active layer 20, the threshold voltage of the channel region 21 can be adjusted to raise the electrical property of the TFT.

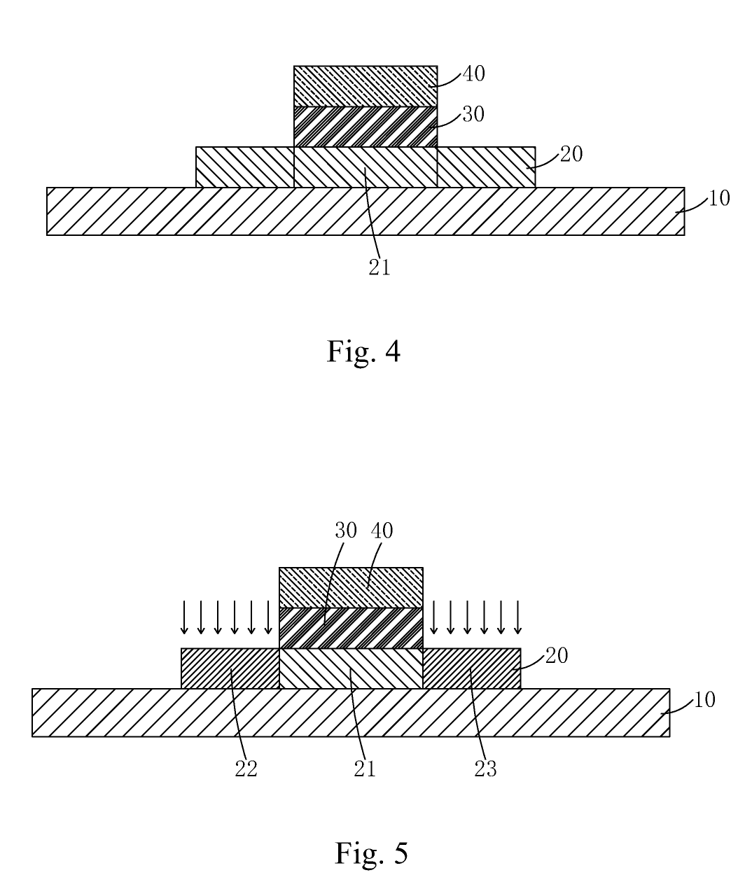

step 2, as shown in FIGS. 3-5, sequentially depositing an isolation layer 32 and a first metal layer 31 on the active layer 20 and the substrate 10, and employing one mask for patterning the first metal layer 31 and the isolation layer 32 to obtain a first gate 40 and a gate isolation layer 30, of which widths are equal to a width of the channel region 21 of the active layer 20, and two ends in a width direction are aligned;

employing the first gate 40 and the gate isolation layer 30 to be a stopper layer, and implementing ion implantation to the active layer 20 to obtain a first ion heavily doped region 22 and a second ion heavily doped region 23, which are respectively at two sides of the channel region 21.

Specifically, the gate isolation layer 30 can be a silicon oxide layer (SiOₓ), a silicon nitride layer (SiNₓ) or a composite layer superimposed with the silicon oxide layer and the silicon nitride layer.

Specifically, material of the first gate 40 is a stack combination of one or more of aluminum (Al), molybdenum (Mo), copper (Cu), silver (Ag).

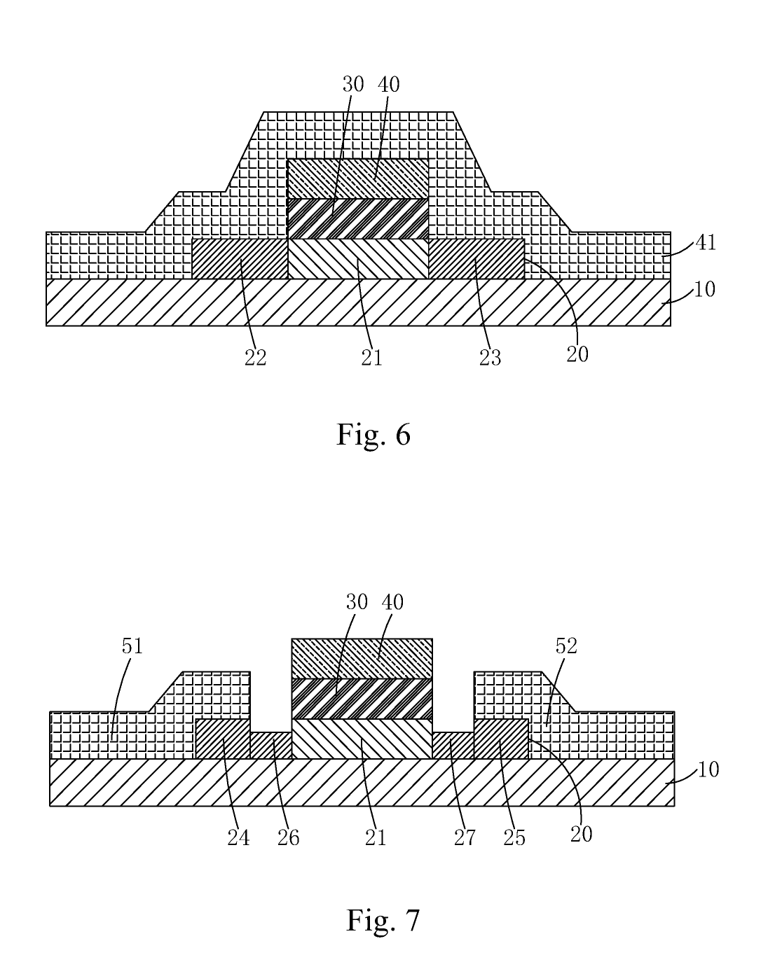

step 3, as shown in FIGS. 6-7, depositing a second metal layer 41 on the first gate 40, the active layer 20 and the substrate 10, and employing one mask for patterning the second metal layer 41 to obtain a source 51 and a drain 52, which are at two sides of the active layer 20 and respectively contact with the first ion heavily doped region 22 and the second ion heavily doped region 23 of the active layer 20;

a portion of the first ion heavily doped region 22 contacting with the source 51 is defined to be a source contact region 24; a portion of the second ion heavily doped region 23 contacting with the drain 52 is defined to be a drain contact region 25.

The source 51, the drain 52 and the first gate 40 are employed to be a stopper layer to etch a portion of the first ion heavily doped region 22 between the source 51 and the first gate 40, and a portion of the second ion heavily doped region 23 between the first gate 40 and the drain 52 for removing an upper portion, of which an ion concentration is higher, and preserving a lower portion, of which an ion concentration is lower, and thus to obtain a first lightly doped offset region 26 between the source contact region 24 and the channel region 21, and a second lightly doped offset region 27 between the channel region 21 and the drain contact region 25.

Specifically, material of the source 51 and the drain 52 is a stack combination of one or more of aluminum (Al), molybdenum (Mo), copper (Cu), silver (Ag).

Specifically, the channel region 21 is a N type ion lightly doped region, and the source contact region 24 and the drain contact region 25 are P type ion heavily doped regions, and the first lightly doped offset region 26 and the second lightly doped offset region 27 are P type ion lightly doped regions; or the channel region 21 is a P type ion lightly doped region, and the source contact region 24 and the drain contact region 25 are N type ion heavily doped regions, and the first lightly doped offset region 26 and the second lightly doped offset region 27 are N type ion lightly doped regions. Preferably, the N type ion is phosphorus ion or arsenic ion; the P type ion is boron ion or gallium ion.

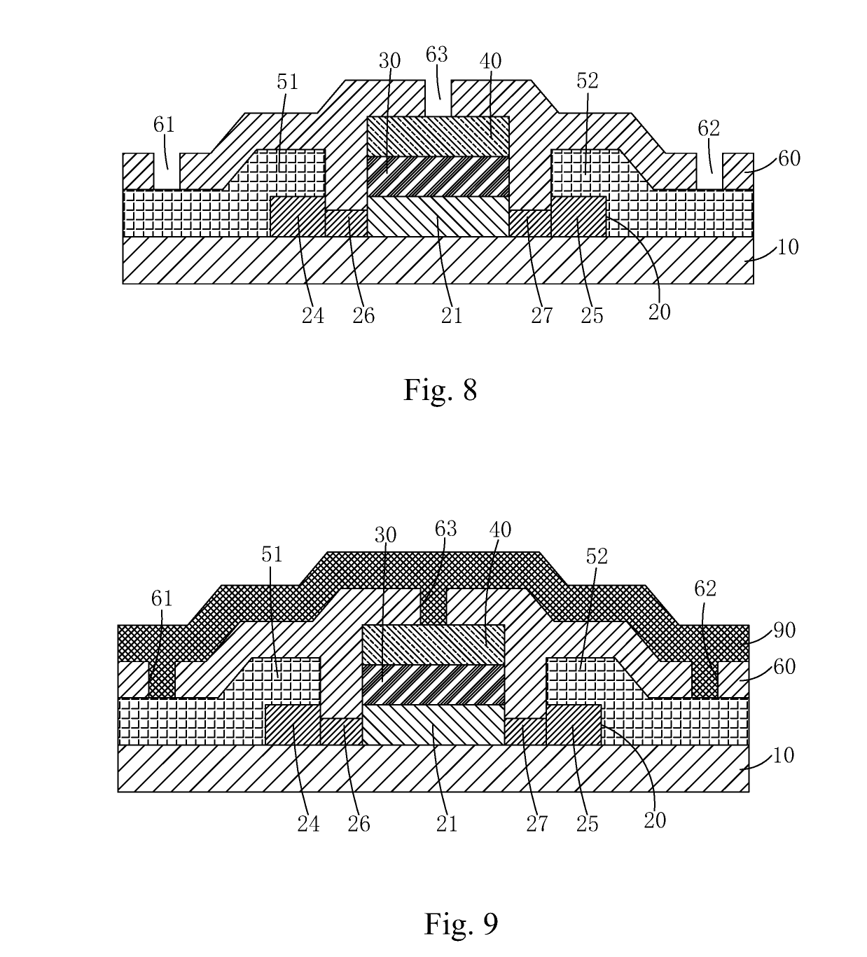

step 4, as shown in FIG. 8, depositing a passivation protective layer 60 on the source 51, the drain 52, the active layer 20 and the first gate 40, and employing one mask for patterning the passivation protective layer 60 to respectively form a first via 61, a second via 62 and a third via 63 correspondingly above the source 51, the drain 52 and the first gate 40.

Specifically, the passivation protective layer 60 can be a silicon oxide layer (SiOₓ), a silicon nitride layer (SiNₓ) or a composite layer superimposed with the silicon oxide layer and the silicon nitride layer.

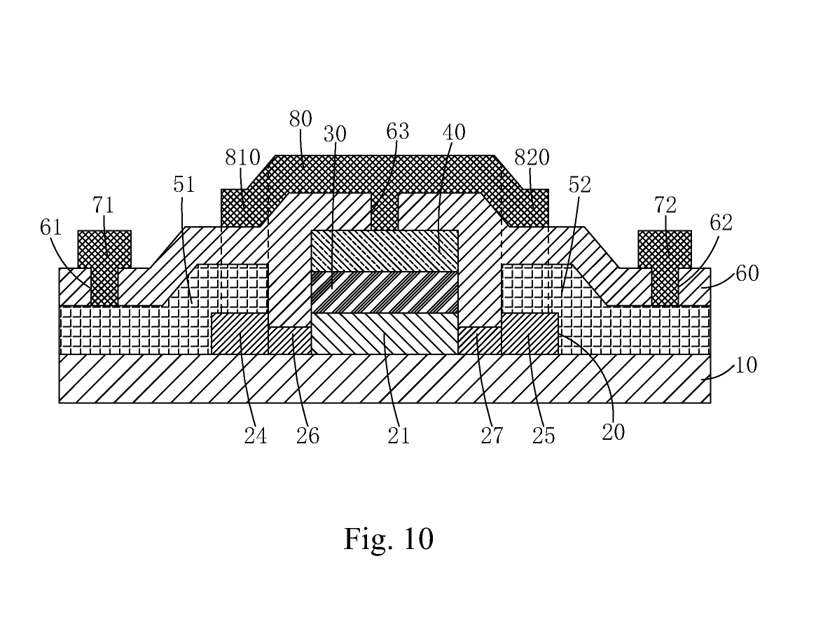

step 5, as shown in FIGS. 9-10, depositing a conductive layer 90 on the passivation protective layer 60, and employing one mask for patterning the conductive layer 90 to obtain a first contact electrode 71, a second contact electrode 72 and a second gate 80, and the first contact electrode 71 and the second contact electrode 72 are respectively coupled with the source 51 and the drain 52 through the first via 61 and the second via 62, and the second gate 80 is coupled to the first gate 40 through the third via 63;

a width of the second gate 80 is larger than a width of the first gate 40, and two sides of the second gate 80 respectively cover the first lightly doped offset region 26 and the second lightly doped offset region 27 at the two sides of the first gate 40.

The present invention employs the first lightly doped offset region 26 and the second lightly doped offset region 27 to be the high resistance regions, which can reduce the off state current of the TFT; the second gate 80 covers the first lightly doped offset region 26 and the second lightly doped offset region 27, and as the TFT is in the on state, the second gate 80 can make the first lightly doped offset region 26 and the second lightly doped offset region 27 generate the carrier accumulation to form the channel and to reduce the resistances of the first lightly doped offset region 26 and the second lightly doped offset region 27 for raising the on state current of the TFT; as the TFT is in the off state, the second gate 80 has no influence to the first lightly doped offset region 26 and the second lightly doped offset region 27, and the first lightly doped offset region 26 and the second lightly doped offset region 27 are kept in high resistance state, which can reduce the off state current of the TFT.

Preferably, a first overlap region 810 is formed between a left side of the second gate 80 and a right side of the source 51, and a second overlap region 820 is formed between a right side of the second gate 80 and a left side of the drain 52. By locating the first overlap region 810 and the second overlap region 820, the on state current of the TFT can be promoted in advance.

Specifically, all materials of the first contact electrode 71, the second contact electrode 72, and the second gate 80 are transparent conductive metal oxide substance, and preferably to be ITO (Indium Tin Oxide).

Specifically, one of the use of the first contact electrode 71 and the second contact electrode 72 is employed to be wires to connect the first source 51 and the second source 52 to the data lines, and another of use is employed to be test points for testing the voltage signals at positions of the first source 51 and the second source 52.

In the aforesaid manufacture method of the TFT substrate, by locating the first lightly doped offset region 26 and the second lightly doped offset region 27 in the TFT, the off state current of the TFT can be reduced; meanwhile, by utilizing the first gate 40 and the second gate 80 to compose the dual gate structure, the influence of the first lightly doped offset region 26 and the second lightly doped offset region 27 to the TFT on state current can be reduced, and the first gate 40 and the second gate 80 are connected, and controlled by the same gate voltage, and no additional voltage is required; the structure is simple and the electrical property is excellent, and the manufactured TFT substrate possesses the better electrical property.

Please refer to FIG. 10. The present invention further provides a TFT substrate, comprising a substrate 10, an active layer 20 located on the substrate 10, a source 51 and a drain 52 located on the active layer 20 and the substrate 10, a gate isolation layer 30 located on the active layer 20, a first gate 40 located on the gate isolation layer 30, a passivation protective layer 60 located on the source 51, the drain 52, the active layer 20 and the first gate 40, and a first contact electrode 71, a second contact electrode 72 and a second gate 80 located on the passivation protective layer 60;

the active layer 20 comprises a channel region 21 in the middle, and a source contact region 24 and a drain contact region 25 at two ends, a first lightly doped offset region 26 between the source contact region 24 and the channel region 21, and a second lightly doped offset region 27 between the channel region 21 and the drain contact region 25;

a first gate 40 and a gate isolation layer 30, of which widths are equal to a width of the channel region 21 of the active layer 20, and two ends in a width direction are aligned;

the passivation protective layer 60 comprises a first via 61, a second via 62 and a third via 63, which are correspondingly above the source 51, the drain 52 and the first gate 40, respectively; the first contact electrode 71 and the second contact electrode 72 are respectively coupled with the source 51 and the drain 52 through the first via 61 and the second via 62, and the second gate 80 is coupled to the first gate 40 through the third via 63;

a width of the second gate 80 is larger than a width of the first gate 40, and two sides of the second gate 80 respectively cover the first lightly doped offset region 26 and the second lightly doped offset region 27 at the two sides of the first gate 40.

Specifically, upper surfaces of the first lightly doped offset region 26 and the second lightly doped offset region 27 are lower than upper surfaces of the channel region 21, the source contact region 24 and the drain contact region 25.

Specifically, the channel region 21 is a N type ion lightly doped region, and the source contact region 24 and the drain contact region 25 are P type ion heavily doped regions, and the first lightly doped offset region 26 and the second lightly doped offset region 27 are P type ion lightly doped regions; or the channel region 21 is a P type ion lightly doped region, and the source contact region 24 and the drain contact region 25 are N type ion heavily doped regions, and the first lightly doped offset region 26 and the second lightly doped offset region 27 are N type ion lightly doped regions. Preferably, the N type ion is phosphorus ion or arsenic ion; the P type ion is boron ion or gallium ion.

Preferably, a first overlap region 810 is formed between a left side of the second gate 80 and a right side of the source 51, and a second overlap region 820 is formed between a right side of the second gate 80 and a left side of the drain 52. By locating the first overlap region 810 and the second overlap region 820, it is beneficial for raising the on state current of the TFT.

Specifically, all materials of the first contact electrode 71, the second contact electrode 72, and the second gate 80 are transparent conductive metal oxide substance, and preferably to be ITO (Indium Tin Oxide).

Specifically, one of the use of the first contact electrode 71 and the second contact electrode 72 is employed to be wires to connect the first source 51 and the second source 52 to the data lines, and another of use is employed to be test points for testing the voltage signals at positions of the first source 51 and the second source 52.

Specifically, the substrate 10 is a glass substrate.

Specifically, material of the active layer 20 is Low Temperature Poly-Silicon.

Specifically, material of the first gate 40, the source 51 and the drain 52 is a stack combination of one or more of aluminum (Al), molybdenum (Mo), copper (Cu), silver (Ag).

Specifically, the gate isolation layer 30 and the passivation protective layer 60 can be silicon oxide layers (SiOₓ), silicon nitride layers (SiNₓ) or composite layers superimposed with the silicon oxide layers and the silicon nitride layers.

In the aforesaid TFT substrate, the first gate 40 and the second gate 80 are employed to compose the dual gate structure, and the first gate 40 and the second gate 80 are connected, and controlled by the same gate voltage, and no additional voltage is required, and the first lightly doped offset region 26 and the second lightly doped offset region 27 among the first gate 40, and the source 51 and the drain 52 are employed to be the high resistance regions, which can reduce the off state current of the TFT; the second gate 80 covers the first lightly doped offset region 26 and the second lightly doped offset region 27, and as the TFT is in the on state, the second gate 80 can make the first lightly doped offset region 26 and the second lightly doped offset region 27 generate the carrier accumulation to form the channel and to reduce the resistances of the first lightly doped offset region 26 and the second lightly doped offset region 27 for raising the on state current of the TFT; as the TFT is in the off state, the second gate 80 has no influence to the first lightly doped offset region 26 and the second lightly doped offset region 27, and the first lightly doped offset region 26 and the second lightly doped offset region 27 are kept in high resistance state, which can reduce the off state current of the TFT.

In conclusion, the present invention provides the manufacture method of the TFT substrate. By locating the first lightly doped offset region and the second lightly doped offset region in the TFT, the off state current of the TFT can be reduced; meanwhile, by utilizing the first gate and the second gate to compose the dual gate structure, the influence of the first lightly doped offset region and the second lightly doped offset region to the TFT on state current can be reduced, and the first gate and the second gate are connected, and controlled by the same gate voltage, and no additional voltage is required; the structure is simple and the electrical property is excellent, and the manufactured TFT substrate possesses the better electrical property. The manufactured TFT substrate of the present invention utilizes the lightly doped offset structure to reduce the off state current of the TFT, and utilizes the dual gate structure to reduce the influence of the lightly doped offset structure to the TFT on state current, and the structure is simple and the electrical property is excellent.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A manufacture method of a TFT substrate, comprising steps of:
step 1, providing a substrate, and forming an active layer on the substrate, and implementing ion implantation to the active layer and defining a channel region on the active layer;
step 2, sequentially depositing an isolation layer and a first metal layer on the active layer and the substrate, and employing one mask for patterning the first metal layer and the isolation layer to obtain a first gate and a gate isolation layer, of which widths are equal to a width of the channel region of the active layer, and two ends in a width direction are aligned;
employing the first gate and the gate isolation layer to be a stopper layer, and implementing ion implantation to the active layer to obtain a first ion heavily doped region and a second ion heavily doped region, which are respectively at two sides of the channel region;
step 3, depositing a second metal layer on the first gate, the active layer and the substrate, and employing one mask for patterning the second metal layer to obtain a source and a drain, which are at two sides of the active layer and respectively contact with the first ion heavily doped region and the second ion heavily doped region of the active layer;
a portion of the first ion heavily doped region contacting with the source is defined to be a source contact region; a portion of the second ion heavily doped region contacting with the drain is defined to be a drain contact region;
the source, the drain and the first gate are employed to be a stopper layer to etch a portion of the first ion heavily doped region between the source and the first gate, and a portion of the second ion heavily doped region between the first gate and the drain for removing an upper portion, of which an ion concentration is higher, and preserving a lower portion, of which an ion concentration is lower, and thus to obtain a first lightly doped offset region between the source contact region and the channel region, and a second lightly doped offset region between the channel region and the drain contact region;
step 4, depositing a passivation protective layer on the source, the drain, the active layer and the first gate, and employing one mask for patterning the passivation protective layer to respectively form a first via, a second via and a third via correspondingly above the source, the drain and the first gate;
step 5, depositing a conductive layer on the passivation protective layer, and employing one mask for patterning the conductive layer to obtain a first contact electrode, a second contact electrode and a second gate, and the first contact electrode and the second contact electrode are respectively coupled with the source and the drain through the first via and the second via, and the second gate is coupled to the first gate through the third via;
a width of the second gate is larger than a width of the first gate, and two sides of the second gate respectively cover the first lightly doped offset region and the second lightly doped offset region at the two sides of the first gate.

2. The manufacture method of the TFT substrate according to claim 1, wherein in the step 1, a specific implementation of forming the active layer on the substrate is: depositing an amorphous silicon thin film on the substrate, and after employing solid phase crystallization to convert the amorphous silicon film into a low temperature polysilicon film, employing one mask for patterning the low temperature polysilicon film to obtain the active layer.

3. The manufacture method of the TFT substrate according to claim 1, wherein the channel region is a N type ion lightly doped region, and the source contact region and the drain contact region are P type ion heavily doped regions, and the first lightly doped offset region and the second lightly doped offset region are P type ion lightly doped regions; or the channel region is a P type ion lightly doped region, and the source contact region and the drain contact region are N type ion heavily doped regions, and the first lightly doped offset region and the second lightly doped offset region are N type ion lightly doped regions.

4. The manufacture method of the TFT substrate according to claim 1, wherein a first overlap region is formed between a left side of the second gate and a right side of the source, and a second overlap region is formed between a right side of the second gate and a left side of the drain.

5. The manufacture method of the TFT substrate according to claim 1, wherein all materials of the first contact electrode, the second contact electrode and the second gate are transparent conductive metal oxide substance.

6. A TFT substrate, comprising a substrate, an active layer located on the substrate, a source and a drain located on the active layer and the substrate, a gate isolation layer located on the active layer, a first gate located on the gate isolation layer, a passivation protective layer located on the source, the drain, the active layer and the first gate, and a first contact electrode, a second contact electrode and a second gate located on the passivation protective layer;
the active layer comprises a channel region in the middle, and a source contact region and a drain contact region at two ends, a first lightly doped offset region between the source contact region and the channel region, and a second lightly doped offset region between the channel region and the drain contact region;
a first gate and a gate isolation layer, of which widths are equal to a width of the channel region of the active layer, and two ends in a width direction are aligned;
the passivation protective layer comprises a first via, a second via and a third via, which are correspondingly above the source, the drain and the first gate, respectively; the first contact electrode and the second contact electrode are respectively coupled with the source and the drain through the first via and the second via, and the second gate is coupled to the first gate through the third via;
a width of the second gate is larger than a width of the first gate, and two sides of the second gate respectively cover the first lightly doped offset region and the second lightly doped offset region at the two sides of the first gate.

7. The TFT substrate according to claim 6, wherein upper surfaces of the first lightly doped offset region and the second lightly doped offset region are lower than upper surfaces of the channel region, the source contact region and the drain contact region.

8. The TFT substrate according to claim 6, wherein the channel region is a N type ion lightly doped region, and the source contact region and the drain contact region are P type ion heavily doped regions, and the first lightly doped offset region and the second lightly doped offset region are P type ion lightly doped regions; or the channel region is a P type ion lightly doped region, and the source contact region and the drain contact region are N type ion heavily doped regions, and the first lightly doped offset region and the second lightly doped offset region are N type ion lightly doped regions.

9. The TFT substrate according to claim 6, wherein a first overlap region is formed between a left side of the second gate and a right side of the source, and a second overlap region is formed between a right side of the second gate and a left side of the drain.

10. The TFT substrate according to claim 6, wherein all materials of the first contact electrode, the second contact electrode and the second gate are transparent conductive metal oxide substance.

11. A TFT substrate, comprising a substrate, an active layer located on the substrate, a source and a drain located on the active layer and the substrate, a gate isolation layer located on the active layer, a first gate located on the gate isolation layer, a passivation protective layer located on the source, the drain, the active layer and the first gate, and a first contact electrode, a second contact electrode and a second gate located on the passivation protective layer;
the active layer comprises a channel region in the middle, and a source contact region and a drain contact region at two ends, a first lightly doped offset region between the source contact region and the channel region, and a second lightly doped offset region between the channel region and the drain contact region;
a first gate and a gate isolation layer, of which widths are equal to a width of the channel region of the active layer, and two ends in a width direction are aligned;
the passivation protective layer comprises a first via, a second via and a third via, which are correspondingly above the source, the drain and the first gate, respectively; the first contact electrode and the second contact electrode are respectively coupled with the source and the drain through the first via and the second via, and the second gate is coupled to the first gate through the third via;
a width of the second gate is larger than a width of the first gate, and two sides of the second gate respectively cover the first lightly doped offset region and the second lightly doped offset region at the two sides of the first gate;
wherein upper surfaces of the first lightly doped offset region and the second lightly doped offset region are lower than upper surfaces of the channel region, the source contact region and the drain contact region;
wherein the channel region is a N type ion lightly doped region, and the source contact region and the drain contact region are P type ion heavily doped regions, and the first lightly doped offset region and the second lightly doped offset region are P type ion lightly doped regions; or the channel region is a P type ion lightly doped region, and the source contact region and the drain contact region are N type ion heavily doped regions, and the first lightly doped offset region and the second lightly doped offset region are N type ion lightly doped regions.

12. The TFT substrate according to claim 11, wherein a first overlap region is formed between a left side of the second gate and a right side of the source, and a second overlap region is formed between a right side of the second gate and a left side of the drain.

13. The TFT substrate according to claim 11, wherein all materials of the first contact electrode, the second contact electrode and the second gate are transparent conductive metal oxide substance.
